(19) United States
(12) Patent Application Publication
(10) Pub. No.: US 2006/0039128 A1
(43) Pub. Date: Feb. 23, 2006

(54) Structure for hanging an electronic device

(75) Inventors: Wen-Ping Chiu, Jhungli City (TW); Wen-Chung Ho, Taoyuan City (TW); Chang-Chien Li, Taoyuan City (TW)

Correspondence Address: REED SMITH LLP, 3110 FAIRVIEW PARK DRIVE, SUITE 1400, FALLS CHURCH, VA, 22042, US

(73) Assignee: BenQ Corporation

(21) Appl. No.: 11/206,178

(22) Filed: Aug. 18, 2005

(30) Foreign Application Priority Data
Aug. 18, 2004 (TW) 93124771

(51) Int. Cl. H05K 7/02

(52) U.S. Cl. 361/807; 361/808; 361/809

(57) ABSTRACT

A structure for hanging an electronic device is provided. The structure includes a supporting element, an adaptive element and a carrying element. The carrying element having a rail is disposed on the electronic device. The rail has an upper supporting plate. The adaptive element has a sliding axle. As the sliding axle slides into the rail, the sliding axle supports the upper supporting plate, and the upper supporting plane limits the vertical movement of the sliding axle. The adaptive element has a receiving space defining an opening. The supporting element passes through the opening and has a bottom plate disposed in the receiving space. In a first state, the bottom plate engages with the adaptive element, but in the second state, a distance exists between the bottom plate and the adaptive element allowing users to adjust the electronic device.

### CLAIM PRIORITY

This application claims the right of priority based on Taiwan Patent Application No. 093124771 filed on Aug. 18, 2004, which is incorporated herein by reference and assigned to the assignee herein.

### FIELD OF THE INVENTION

The present invention relates to a structure for hanging an electronic device, and in particular, for hanging an image output device, such as an overhead projector.

### BACKGROUND OF THE INVENTION

There is a need to hang an electronic device, especially an image output device, such as an overhead projector, on the ceiling or other objects for effectively utilizing limited available space. Therefore, improved structures for hanging the image output device have been constantly introduced in order that the image output device can be used in a conference room, a media center, a control center, a gymnasium and a home theater in a convenient manner.

Conventionally, the hanging structure and the electronic device are fixed together by screws, such that the heavy electronic device (the weight of the overhead projector is about 4-10 kg) can be mounted securely. At least two persons are needed for hanging the electronic device. One person supports the electronic device and the other one fixes the hanging structure to the electronic device by the screws. However, it is not convenient for hanging the heavy electronic device on the ceiling by multiple persons at the same time, and the electronic device may fall from the ceiling accidentally, thereby the electronic device is damaged.

Moreover, for the image output device, its vertical position, tilt angle need to be adjusted, or its body need to be rotated to optimize the output image. However, the adjustment requires at least two people working together.

As mentioned above, hanging and adjusting the electronic device conventionally needs lots of efforts, resulting in the utilization of the electronic device being limited. Therefore, an improved structure with operation convenience for hanging the electronic device is desired.

### SUMMARY OF THE INVENTION

One aspect of the present invention is to provide a structure for hanging an electronic device by a single person to improve the operation convenience of hanging the electronic device.

Another aspect of the present invention is to provide a structure for hanging an electronic device, under which the electronic device can be adjusted by a single person, for enhancing the utilization of the electronic device.

A structure for hanging an electronic device in accordance with the present invention comprises an adaptive element for connecting the electronic device and a supporting element for supporting the adaptive element. The adaptive element includes a receiving space defining an opening. The supporting element passes through the opening and has a bottom plate disposed within the receiving space. The structure selectively has a first state and a second state. In the first state, the bottom plate is engaged with the adaptive element. In the second state, a distance exists between the bottom plate and the adaptive element allowing users to adjust the electronic device.

A structure for hanging an electronic device in accordance with the present invention comprises an adaptive element for connecting the electronic device and a carrying element fixed on the electronic device. The adaptive element includes a sliding axle. The carrying element has a rail with an upper supporting plate. As the sliding axle slides into the rail, the sliding axle supports the upper supporting plate, and the upper supporting plane limits the vertical movement of the sliding axle.

### BRIEF DESCRIPTION OF THE DRAWINGS

FIG. 1(a) is a schematic diagram of a structure of the present invention for hanging an electronic device.

FIG. 1(b) is a partially enlarged schematic diagram of a sliding axle and a rail of the present invention.

FIG. 2 is a schematic diagram for hanging the electronic device.

FIG. 3 is a schematic diagram showing that the structure of the present invention connects to the electronic device (a first state).

FIG. 4 is an enlarged explosive diagram of components in FIG. 3.

FIG. 5 is a schematic diagram showing that the structure of the present invention connects to the electronic device (a second state).

FIG. 6 is a top view schematic diagram showing that the structure of the present invention connects to the electronic device.

FIG. 7(a) is a side view schematic diagram showing that the structure of the present invention connects to the electronic device.

FIG. 7(b) is a side view schematic diagram showing that the structure of the present invention connected to the electronic device is adjusted.

FIG. 8(a) is a side view schematic diagram of the supporting element of the present invention.

FIG. 8(b) is a perspective schematic diagram of the supporting element as the electronic device is adjusted.

### DETAILED DESCRIPTION

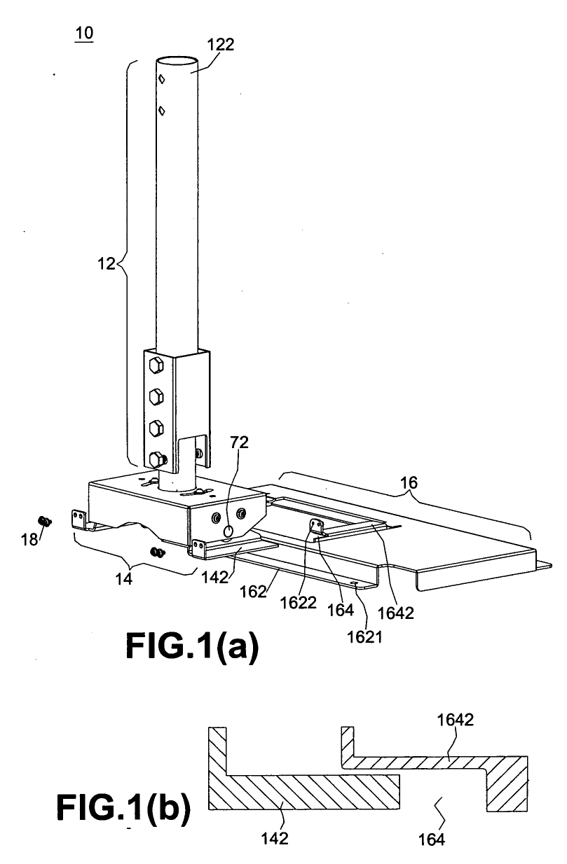

A structure for hanging an electronic device is disclosed in FIG. 1(a). The structure 10 includes a supporting element 12, an adaptive element 14 and a carrying element 16. The supporting element 12 connects to the adaptive element 14. One edge 122 of the supporting element 12 is fixed to the ceiling 25. The carrying element 16 includes a base 162. The base 162 defines a screw hole 1621, such that a screw can pass through the screw hole 1621 to secure the carrying element 16 on the top of the electronic device (not shown). The base 162 has a rail 164 and the rail 164 has an upper supporting plane 1642. A sliding axle 142 corresponding to the rail 164 is disposed on the bottom of the adaptive element 14. The sliding axle 142 can move within the rail 164, as shown in FIG. 1(b).

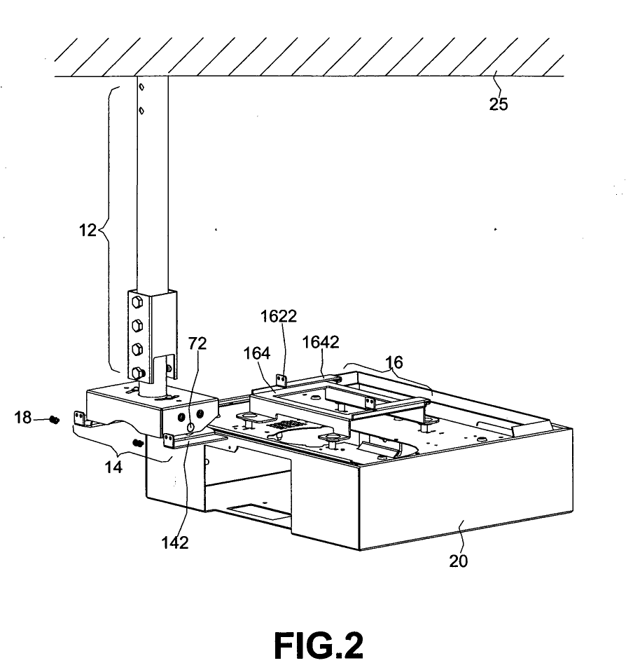

FIG. 1(b) is an enlarged view of the rail 164 and the sliding axle 142. As the sliding axle 142 slides into the rail 164, the sliding axle 142 contacts the upper supporting plane 1642, and the upper supporting plane 1642 limits the vertical movement of the sliding axle 142, such that the electronic device (not shown) fixed on the carrying element 16 can be supported. The upper supporting plane 1642 in FIG. 1(a) is formed from the base 162 of the carrying element 16 and vertical to the sliding axle 142, thereby the rail 164 can be formed. In another embodiment, referring to FIG. 2, the upper supporting plane 1642 is also formed from the base 162 of the carrying element 16, but is parallel to the sliding axle 142.

FIG. 2 is a schematic diagram showing an electronic device 20 hanging on the ceiling 25. The adaptive element 14 is connected to the supporting element 12 fixed on the ceiling 25, and the carrying element 16 is fastened on the top of the electronic device 20. An user only needs to slide the sliding axle 142 into the rail 164 by a single hand, and renders a screw 18 passing through the screw hole 1622 to fasten the adaptive element 14 to the carrying element 16, such that the electronic device 20 is hung on the ceiling 25. As a result, the electronic device 20 is assembled by a single person alone, making the assembly of the electronic device 20 more convenient. In addition, only the supporting element 12 and the adaptive element 14 need to be fixed on the ceiling 25 for a long-term, and the electronic device 20 is not necessary. As the user needs to utilize the electronic device 20, the user has to connect the carrying element 16 with the adaptive element 14 to hang the electronic device 20. So the electronic device 20 does not have to be hung on the ceiling 25 while being not used, preventing the electronic device from being contaminated.

The sliding axle 142 supports the upper supporting plane 1642, and the upper supporting plane 1642 limits the vertical movement of the sliding axle 142 after the sliding axle 142 slides into the rail 164, so that the electronic device 20 is hung on the ceiling 25. The screw 18 passes through the screw hole 1622, making the adaptive element 14 and the carrying element 16 fixed together, and therefore, to prevent the relative movement between the sliding axle 142 and the rail 164. The screw 18 and the screw hole 1622 are preferred embodiments of the present invention, and any other conventional elements suitable for fixing the adaptive element 14 to the carrying element 16 can be used herein. In addition, the position of the sliding axle 142 and the rail 164 may be reversed in accordance with another embodiment, i.e., the rail 164 is disposed on the adaptive element 14, and the sliding axle 142 is disposed on the carrying element 16. The user can slide the sliding axle 142 into the rail 164, and fasten the adaptive element 14 to the carrying element 16 subsequently to hang the electronic device 20 on the ceiling 25.

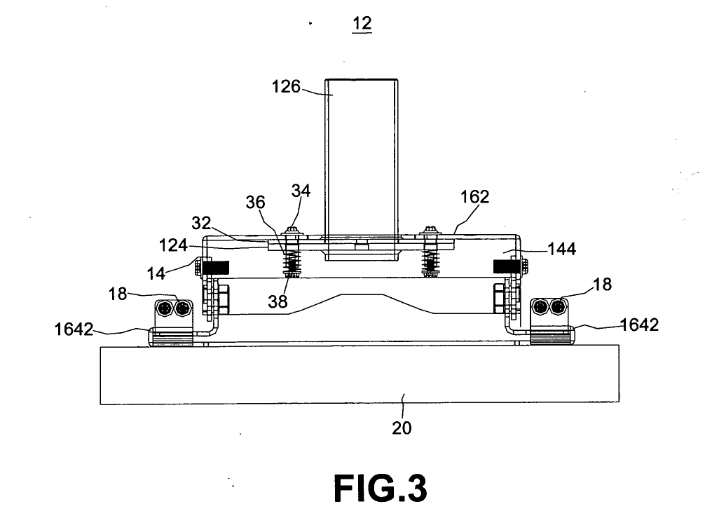

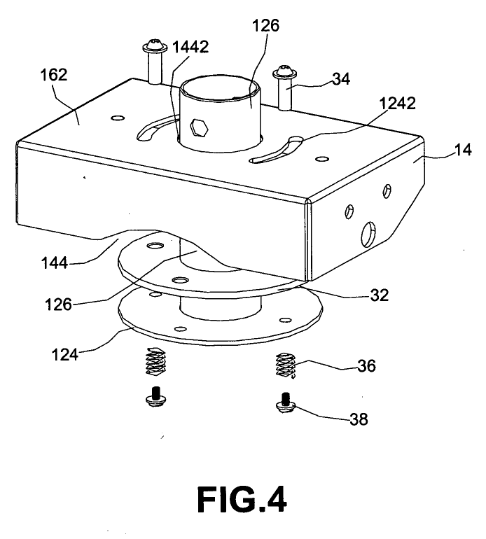

Referring to FIGS. 3 and 4, FIG. 3 is a schematic diagram showing the structure of the present invention is connected to the electronic device 20, and FIG. 4 is the enlarged explosive diagram of components in FIG. 3. The adaptive element 14 includes a receiving space 144 defining an opening 1442. The supporting element 12 has a bottom plate 124 disposed within the receiving space 144 and a hanging rod 126 passing through the opening 1442. A pad 32 disposed between the bottom plate 124 and the base 162 is used to provide a friction between the bottom plate 124 and the base 162. Other than the pad, any other means suitable for providing friction between the bottom plate 124 and the base 162 can be used herein, for example, the bottom plate 124 with an embossed surface. The base 162 includes positioning holes 1242, such as a pair of camber-shaped holes disposed on the opposite side of hanging rod 126. A pair of the connecting elements, namely positioning screws 34, pass through the positioning holes 1242, and connect to the bottom plate 124, the pad 32, the base 162 and the elastic element 36, and further engage the positioning screw nuts 38.

The structure 10 selectively poses a first state and a second state. In the first state, referring to FIG. 3, since the electronic device 20 connects to the adaptive element 14 and the bottom plate 124 of the supporting element 12 supports the base 162 of the adaptive element 16, and then the electronic device 20 is supported. The friction between the bottom plate 124 and the base 162 limits the undesired movement of the electronic device 20, which may be caused by the external shaking. The bottom plate 124 and the base 162 engaged with each other tightly, resulting in a stable hanging status of the electronic device 20.

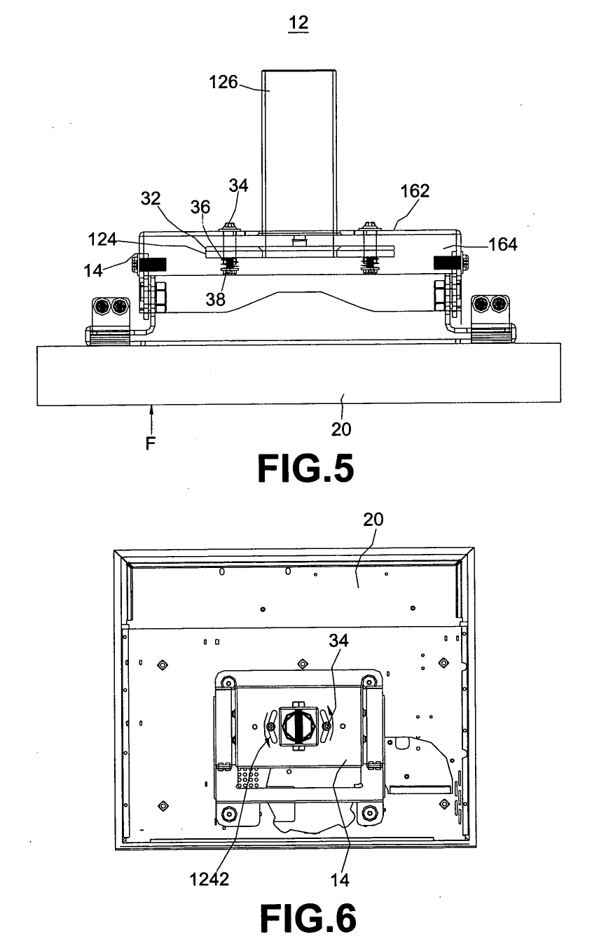

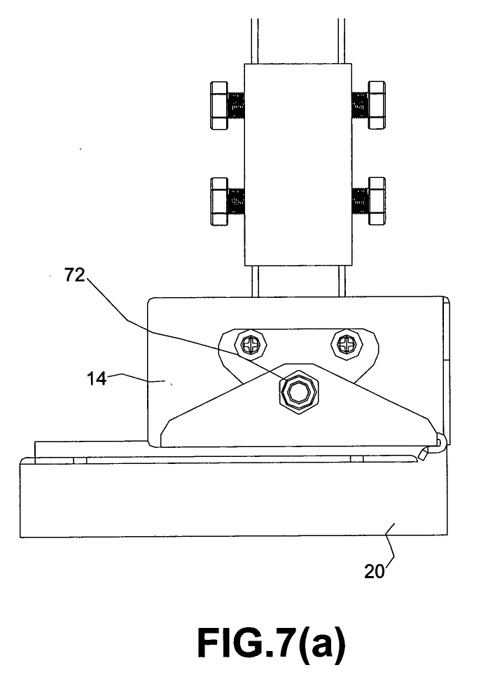

Referring to FIG. 5, as the user wants to adjust the position of the electronic device 20, the user has to provide a force (F) against the gravity applied on the electronic device 20, making the elastic element (e.g., spring 36) compressed, and a distance therefore exists between the bottom plate 124 and the base 162. At this time, the structure 10 is in the second state. FIG. 6 is a top schematic diagram showing that the structure 10 connects to the electronic device 20. The user rotates the electronic device 20, making the connecting element 34 move along the sidewall of the positioning hole 1242 (shown as arrowheads in FIG. 6) until a predetermined position. And then he releases F, resulting in the re-engagement of the bottom plate 124 with the base 162. The arc of the positioning hole 1242 limits the rotation angle of the electronic device 20. The arc of the positioning hole 1242 is about 30 degrees in accordance with one embodiment of the present invention.

The friction between the bottom plate 124 and the base 162 provided by the pad 32 or other suitable means ensures that the bottom plate 124 engages with the base 162 tightly. The elastic element 36 is used to compress the pad 32 and increase the friction to limit the movement of the electronic device 20. Therefore, as the user adjusts the electronic device 20 hanging on the ceiling 25, the user only has to push the electronic device 20 and rotate the electronic device 20 to the predetermined position.

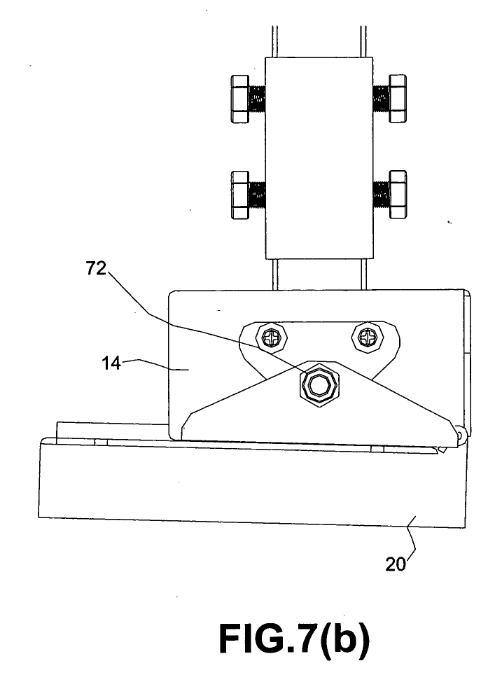

The adaptive element 14 includes a hinge 72 for adjusting the tilt angle of the electronic device 20 as shown in FIG. 7(a). The hinge 72 is composed of a plurality of plastic plates, such that the tilt angle can be adjusted as desired as shown in FIG. 7(b). The tilt angle will be limited due to the friction between the plurality of plastic plates.

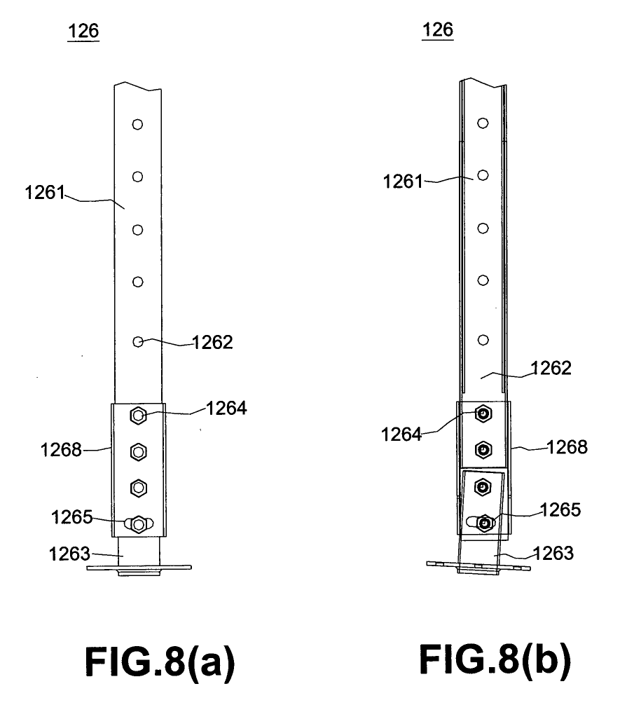

FIGS. 8(a) and 8(b) are partially enlarged schematic diagram of the hanging rod 126. The hanging rod 126 includes a first supporting portion 1261 for connecting to the ceiling (not shown), a second supporting portion 1263 for connecting to the electronic device (not shown) and a third supporting portion 1268 for connecting the first supporting portion 1261 and the second supporting portion 1263. The first supporting portion 1261 and the second supporting portion 1263 includes a plurality of holes 1262 respectively, and the third supporting portion 1268 includes a plurality of screw nuts 1264 corresponding to the plurality of holes 1262. With the screw passing through one of the plurality of holes 1262 and engaging one of the plurality of screw nuts 1264, the vertical position of the electronic device (not shown) is determined. In addition, hole 1262 may be camber-shaped hole, and thereby the electronic device (not shown) can be tilted, as shown in FIG. 8(b).

By means of the detailed descriptions of what is presently considered to be the most practical and preferred embodiments of the subject invention, it is the expectation that the features and the gist thereof are plainly revealed. Nevertheless, these above-mentioned illustrations are not intended to be construed in a limiting sense. Instead, it should be well understood that any analogous variation and equivalent arrangement is supposed to be covered within the spirit and scope to be protected and that the interpretation of the scope of the subject invention would therefore as much broadly as it could apply.

What claim is:

1. A structure for hanging an electronic device, comprising:
an adaptive element for connecting the electronic device, the adaptive element including a receiving space defining an opening; and
a supporting element for supporting the adaptive element, the supporting element passing through the opening and having a bottom plate disposed within the receiving space;
wherein the structure selectively has a first state and a second state:
in the first state, the bottom plate is engaged with the adaptive element; and
in the second state, a distance exists between the bottom plate and the adaptive element allowing users to adjust the electronic device.

2. The structure of claim 1 further comprising a pad disposed between the bottom plate and the supporting element for providing a friction between the bottom plate and the supporting element.

3. The structure of claim 1 further comprising a connecting element, and the adaptive element including a hole, wherein the connecting element passes through the hole to connect with the bottom plate, and the connecting element moves along a sidewall of the hole, responsive to a movement of the electronic device, to limit a rotation angle of the electronic device.

4. The structure of claim 3, wherein the hole is a camber-shaped hole.

5. The structure of claim 3, wherein the connecting element is a screw.

6. The structure of claim 1, wherein the adaptive element further includes a hinge for adjusting a tilt angle of the electronic device.

7. The structure of claim 1, wherein the supporting element includes a plurality of holes and a plurality of screw nuts corresponding to the plurality of holes, and a vertical position of the electronic device is determined by allowing a screw passing through one of the plurality of holes and engaging with one of the plurality of screw nuts.

8. The structure of claim 1 further comprising a sliding axle and a rail, wherein the sliding axle is disposed on the adaptive element, the rail having an upper supporting plane is disposed on the electronic device, and as the sliding axle slides into the rail, the sliding axle supports the upper supporting plate, and the upper supporting plane limits the vertical movement of the sliding axle.

9. The structure of claim 8, wherein the sliding axle and the rail are fixed together by a screw.
